(19) United States
(12) Patent Application Publication
(10) Pub. No.: US 2024/0168322 A1
(43) Pub. Date: May 23, 2024

(54) QUANTUM DOT COMPLEX, THREE-DIMENSIONAL DISPLAY ELEMENT, AND PROCESS FOR QUANTUM DOT COMPLEX

(71) Applicant: ANHUI EASPEED TECHNOLOGY CO., LTD., Hefei (CN)

(72) Inventors: Liangliang ZHANG, Shanghai (CN); Chengfei HAN, Shanghai (CN)

(21) Appl. No.: 18/389,814

(22) Filed: Dec. 20, 2023

Related U.S. Application Data
(63) Continuation of application No. PCT/CN2022/100379, filed on Jun. 22, 2022.

(30) Foreign Application Priority Data
Jun. 23, 2021 (CN) 202110701334.1

(51) Int. Cl. G02F 1/017; B05D 1/00; B82Y 20/00; B82Y 40/00; C09J 133/00; C09J 163/00; C09K 11/02

(52) U.S. Cl. CPC G02F 1/01791; B05D 1/005; B82Y 20/00; B82Y 40/00; C09J 133/00; C09J 163/00; C09K 11/025

(57) ABSTRACT

The present disclosure discloses a quantum dot complex, a three-dimensional display element, and a process for a quantum dot complex. The process for the quantum dot complex includes: sequentially providing a first transparent conductive layer, coating a quantum dot layer, and providing a second transparent conductive layer, on a side of a transparent substrate to form a quantum dot unit; bonding a plurality of quantum dot units; and obtaining the quantum dot complex by trimming the bonded quantum dot units.

### CROSS-REFERENCE TO RELATED APPLICATION

This application is a continuation of International Application No. PCT/CN2022/100379, filed on Jun. 22, 2022, which claims priority to Chinese Patent Application No. 202110701334.1 filed on Jun. 23, 2021, the entire disclosure of which is incorporated herein by reference.

### FIELD

The present disclosure relates to the field of display technologies, and more particularly, to a quantum dot complex, a three-dimensional display element, and a process for the quantum dot complex.

### BACKGROUND

The existing solid-state volumetric three-dimensional display technologies, such as a three-dimensional display technology based on an up-conversion material and a three-dimensional display technology of liquid crystal lamination, have their respective shortcomings. The former has low brightness and poor contrast, and the latter has low longitudinal resolution and a single viewing angle.

### SUMMARY

The present disclosure aims to solve at least one of the technical problems existing in the prior art. To this end, an object of the present disclosure is to provide a quantum dot complex, a three-dimensional display element, and a processing method for a quantum dot complex.

According to embodiments of a first aspect of the present disclosure, provided is a process for a quantum dot complex. The process for the quantum dot complex includes: sequentially providing a first transparent conductive layer, coating a quantum dot layer, and providing a second transparent conductive layer, on a side of a transparent substrate to form a quantum dot unit; bonding a plurality of quantum dot units; and obtaining the quantum dot complex by trimming the bonded quantum dot units.

The processing process proposed in the present disclosure can significantly improve uniformity of a light-emitting surface in each layer of a bulk material for three-dimensional display, light-emitting contrast, material transparency, depth resolution, and increase a viewing angle of a three-dimensional image, and the like.

In some embodiments, said bonding the plurality of quantum dot units includes: providing a spacer on at least one side of each of the plurality of quantum dot units, in which the spacer is a transparent high polymer material member, a resin member, an optical glass member, or an optical crystal member; laminating the plurality of quantum dot units to form a lamination body, in which adjacent ones of the plurality of quantum dot units are spaced apart from each other by the spacer to form a gap for accommodating an adhesive; sealing two opposite side surfaces of the lamination body, and using another two opposite side surfaces of the lamination body as an adhesive introducing surface and an adhesive discharging surface; and injecting the adhesive to introduce the adhesive from the adhesive introducing surface and fill the gap, to form a layer of cured adhesive containing the spacer between the adjacent quantum dot units.

In some embodiments, the spacer has a height ranging from 1 μm to 500 μm. A distance between adjacent spacers ranges from 0.1 mm to 5 mm. An error on the heights of a plurality of spacers is smaller than or equal to 2 μm.

In some embodiments, a distance between adjacent spacers ranges from 5 μm to 20 mm. The spacer is selectable from one of silicon dioxide microsphere, polystyrene microsphere, and polymethyl methacrylate microsphere. The spacer has a spherical diameter ranging from 1 μm to 200 μm. An error on consistency of the diameter is smaller than 10%.

In some embodiments, the process further includes, prior to sealing the two opposite side surfaces of the lamination body or curing the adhesive: adjusting parallelism and planeness of the lamination body to control an error on each of the parallelism and the planeness within ±5 μm.

In some embodiments, the lamination body is sealed by using a liquid sealant or a solid sealant. The liquid sealant is an epoxy resin or an acrylic resin, and the solid sealant is a rubber plate or a silicone adhesive. The liquid sealant has viscosity greater than 20000 cps, and is hardened through normal-temperature natural hardening, heating hardening, or ultraviolet irradiation hardening. The hardened liquid sealant has shore hardness ranging from 20 A to 70 A.

In some embodiments, the adhesive is defoamed before being injected. The adhesive has viscosity smaller than 500 cps. The adhesive is an epoxy resin or an acrylic resin. The cured adhesive has a volume shrinkage rate smaller than 1.1%, shore hardness ranging from 60 D to 80 D, and a refractive index same as a refractive index of the transparent substrate.

In some embodiments, the adhesive is injected through one of a first gravity injection, a second gravity injection, a first pressure injection, a second pressure injection, and a vacuum injection. The first gravity injection includes: placing the adhesive introducing surface of the lamination body in an adhesive pool of a gravity adhesive feeding device; connecting sealingly the gravity adhesive feeding device and the adhesive introducing surface through a sealing material or a sealing tool; placing the lamination body and the adhesive feeding device into a vacuum chamber of a vacuum device, filling the gap with the adhesive through gravity of the adhesive and a capillary of the adhesive; closing the vacuum device in response to observing the adhesive uniformly seeps at all positions of the adhesive discharging surface; and completing the injection of the adhesive. The second gravity injection includes: placing the adhesive introducing surface of the lamination body in an adhesive pool of a gravity adhesive feeding device; connecting sealingly the gravity adhesive feeding device and the adhesive introducing surface through a sealing material or a sealing tool; connecting a vacuum device at the adhesive discharging surface to wrap the entire adhesive discharging surface of the lamination body; isolating the adhesive discharging surface from an external environment through the sealing material or the sealing tool; setting an absolute vacuum degree of the vacuum device to be smaller than 10 kpa; closing the vacuum device in response to observing the adhesive uniformly seeps at all positions of the adhesive discharging surface; and completing the injection of the adhesive. The first pressure injection includes: placing the adhesive introducing surface of the lamination body in an adhesive of a pressure adhesive feeding device; connecting sealingly the pressure adhesive feeding device and the adhesive introducing surface through a sealing material or a sealing tool; applying a mechanical pressure to allow the gap to be full of the adhesive; monitoring an adjustment pressure by a pressure sensor mounted at the pressure adhesive feeding device to control an adhesive feeding speed; closing a pressure applying device in response to observing the adhesive uniformly seeps at all positions of the adhesive discharging surface; and completing the injection of the adhesive. The second pressure injection includes: placing the adhesive introducing surface of the lamination body in an adhesive of a pressure adhesive feeding device; connecting sealingly the pressure adhesive feeding device and the adhesive introducing surface through a sealing material or a sealing tool; applying an atmospheric pressure to allow the gap to be full of the adhesive; monitoring an adjustment air pressure by an air flow valve mounted at the pressure adhesive feeding device to control an adhesive feeding speed; closing a pressure applying device in response to observing the adhesive uniformly seeps at all positions of the adhesive discharging surface; and completing the injection of the adhesive. The vacuum injection includes: immersing the adhesive introducing surface of the lamination body in an adhesive pool containing the adhesive to liquid-seal the entire adhesive introducing surface by the adhesive; connecting a vacuum device at the adhesive discharging surface to wrap the entire adhesive discharging surface of the lamination body by the vacuum device; isolating the adhesive discharging surface from an external environment through a sealing material or a sealing tool; setting an absolute vacuum degree of the vacuum device to be smaller than 10 kpa; closing the vacuum device in response to observing the adhesive uniformly seeps at all positions of the adhesive discharging surface; and and completing the injection of the adhesive.

In some embodiments, said bonding the plurality of quantum dot units includes: placing, subsequent to a first one of the plurality of quantum dot units being coated with the adhesive, a second one of the plurality of quantum dot units on the adhesive for bonding, repeating this process to form a laminated structure; and adjusting parallelism and flatness of the laminated structure prior to curing the laminated structure.

In some embodiments, the adhesive preferably has viscosity smaller than 1000 cps. The adhesive is an epoxy resin or an acrylic resin. The cured adhesive has a volume shrinkage rate smaller than 1.1% and shore hardness ranging from 60D to 80D.

In some embodiments, processing the plurality of quantum dot units includes: coating a first photoresist layer at a side of the transparent substrate; exposing and developing to retain a part of the first photoresist layer to form a first residue portion; plating the first transparent conductive layer at an exposure and development side of the transparent substrate; peeling the first residue portion to form a first protrusion, in which the first protrusion is located at a side of a peeling region on the first transparent conductive layer, and configured to be connected to a first electrode; coating the quantum dot layer at a side where the first transparent conductive layer is located; coating a second photoresist layer; exposing and developing to retain a part of the second photoresist layer to form a second residue portion, in which the second residue portion and the first residue portion are arranged close to an edge of the transparent substrate; plating the second transparent conductive layer at the exposure and development side of the transparent substrate; and peeling the second residual portion to form a second protrusion on the second transparent conductive layer. The second protrusion is located at a side of the second residual portion, and configured to be connected to a second electrode. The first protrusion is offset from the second protrusion.

According to embodiments of a second aspect of the present disclosure, provided is a processing method for a three-dimensional display element. The processing method for the three-dimensional display element includes: the process for the quantum dot complex as described above; providing a first electrode and a second electrode, in which the first electrode is electrically connected to a first transparent conductive layer of each quantum dot unit, and the second electrode is electrically connected to a second transparent conductive layer of each quantum dot unit; and attaching a circuit board to a side of the quantum dot complex, and connecting the circuit board to the first electrode and the second electrode.

According to embodiments of a third aspect of the present disclosure, provided is a quantum dot complex. The quantum dot complex includes a plurality of quantum dot units sequentially laminated and bonded to each other in a thickness direction. Each of the plurality of quantum dot units includes a transparent substrate, a first transparent conductive layer, a second transparent conductive layer, a quantum dot layer. The first transparent conductive layer and the quantum dot layer are located at a side of the transparent substrate and sequentially arranged away from the transparent substrate. The second transparent conductive layer is located at another side of the transparent substrate or located outside the quantum dot layer. One of the first transparent conductive layer and the second transparent conductive layer is a P-type semiconductor, and another one of the first transparent conductive layer and the second transparent conductive layer is an N-type semiconductor. The quantum dot layer, the first transparent conductive layer, and the second transparent conductive layer of a quantum dot unit where the first transparent conductive layer is located or of a quantum dot unit adjacent to the quantum dot unit where the first transparent conductive layer is located are formed as a PN junction.

In some embodiments, the quantum dot complex has a surface formed as a laser incident surface; and in a lamination direction of the quantum dot units, the greater a distance from the laser incident surface, the greater a thickness of the quantum dot unit.

In some embodiments, the quantum dot layer has a thickness ranging from 0.05 μm to 10 μm; the transparent substrate has a thickness ranging from 0.1 mm to 0.5 mm; an error of parallelism and planeness of each of an upper smooth surface and a lower smooth surface of the transparent substrate is smaller than or equal to ±2 μm; and a length a and a width b of the transparent substrate satisfy 1 mm≤a≤500 mm, and 1 mm≤b≤500 mm.

In some embodiments, a quantum dot layer of each quantum dot unit is configured to emit light in one color when being irradiated; or every three adjacent quantum dot units are defined as a color adjustment group. Quantum dot layers of three quantum dot units in each color adjustment group are configured to respectively emit red light, green light, and blue light when being irradiated.

According to embodiments of a fourth aspect of the present disclosure, provided is a three-dimensional display element. The three-dimensional display element includes: the quantum dot complex as described above; and a circuit board electrically connected to a first transparent conductive layer and a second transparent conductive layer of each quantum dot unit by a first electrode and a second electrode, respectively.

Aiming at the problems existing in the existing solid-state volumetric three-dimensional display technology, the patent focuses on addressing problems from five aspects: \textcircled{1} the uniformity of the light-emitting surface, \textcircled{2} high material transparency, \textcircled{3} high depth resolution, \textcircled{4} achieving viewing of the image at 360°, and \textcircled{5} achieving full-color large-format three-dimensional display.

Additional aspects and advantages of the present disclosure will be provided at least in part in the following description, or will become apparent at least in part from the following description, or can be learned from practicing of the present disclosure.

### BRIEF DESCRIPTION OF THE DRAWINGS

The above and/or additional aspects and advantages of the present disclosure will become apparent and readily appreciated from the following description of the embodiments in conjunction with the accompanying drawings, in which:

FIG. 1 is a schematic diagram of a process for a quantum dot complex according to an embodiment of the present disclosure.

FIG. 2 is a schematic diagram of a processing method for a three-dimensional display element according to an embodiment of the present disclosure.

FIG. 3 is a schematic diagram of a processing method for a three-dimensional display element according to a specific embodiment of the present disclosure.

FIG. 4 is a process flow diagram of processing a quantum dot complex in a lamination manner according to an embodiment of the present disclosure.

FIG. 5 is a schematic diagram of a quantum dot complex according to an embodiment of the present disclosure.

FIG. 6 is a schematic diagram of split of a quantum dot complex according to an embodiment of the present disclosure.

FIG. 7 is a schematic diagram of arrangement of a spacer of a quantum dot complex according to an embodiment of the present disclosure.

FIG. 8 is a schematic diagram of arrangement of a spacer of a quantum dot complex according to another embodiment of the present disclosure.

FIG. 9 is a schematic diagram of arrangement of a spacer of a quantum dot complex according to yet another embodiment of the present disclosure.

FIG. 10 is a schematic diagram of arrangement of a quantum dot unit and a spacer of a quantum dot complex according to an embodiment of the present disclosure.

FIG. 11 is a schematic diagram of applying a pressure to a quantum dot unit and a spacer of a quantum dot complex according to an embodiment of the present disclosure.

FIG. 12 is a schematic diagram of arranging a sealant by a quantum dot complex according to an embodiment of the present disclosure.

FIG. 13 to FIG. 17 are schematic diagrams of an adhesive injection manner according to various embodiments of the present disclosure.

FIG. 18 is a schematic diagram of a display element.

FIG. 19 to FIG. 21 are schematic diagrams of a quantum dot complex bonded in a lamination manner according to an embodiment of the present disclosure.

### REFERENCE NUMERALS

quantum dot complex 100, electrode 20,
quantum dot unit 10, transparent substrate 11, first transparent conductive layer 12, quantum dot layer 13, second transparent conductive layer 14.
spacer 20, sealant 30, rigid plate body 40,
adhesive pool 51, bonding glue a, vacuum chamber 52, adhesive 60, seal 70.

### DETAILED DESCRIPTION

Embodiments of the present disclosure are described in detail below, and the embodiments described with reference to the drawings are exemplary. The embodiments of the present disclosure are described in detail below.

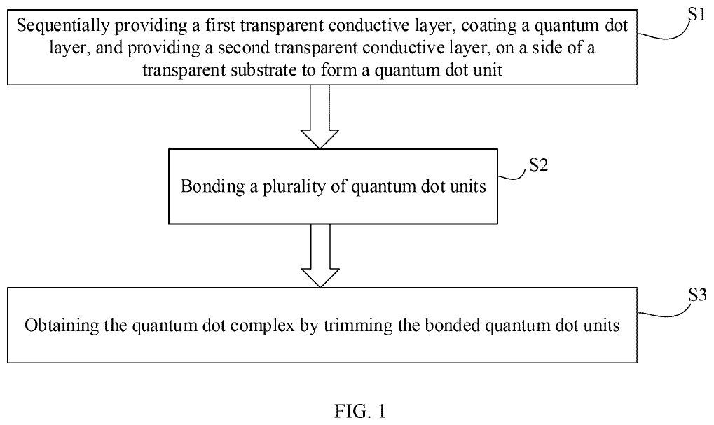

A process for a quantum dot complex according to the embodiments of the present disclosure is described with reference to FIG. 1 to FIG. 21.

As illustrated in FIG. 1, a process for a quantum dot complex according to embodiments of a first aspect of the present disclosure includes the following steps.

At S1, a quantum dot unit is formed by sequentially providing a first transparent conductive layer, coating a quantum dot layer, and providing a second transparent conductive layer, on a side of a transparent substrate. In an exemplary embodiment of the present disclosure, during preparation of the transparent substrate, an ultra-thin glass flat plate manufactured by such processes, like a floating method, an overflow stretching method, a slit stretching method, and a secondary stretching method, may be selected. Moreover, a thickness of a base material ranges from 0.1 mm to 5 mm. Surface type detection is performed on the glass flat plate, to ensured that an error of parallelism and planeness of each of an upper smooth surface and a lower smooth surface of the transparent substrate is smaller than or equal to ±2 μm. A length a and a width b of a glass unit are preferably in a range of: 1 mm≤a≤500 mm, and 1 mm≤b≤500 mm. In addition, a resin transparent plate may also be selected as the base material.

Transparent glass is used as the transparent substrate. In an exemplary embodiment of the present disclosure, a transparent conductive layer may be made of an ITO material or other transparent conductive materials. When an ITO layer is used as the transparent conductive layer, a layer of a first ITO layer is plated on the transparent substrate. A layer of light-emitting quantum dots is spin-coated on the first ITO layer. Finally, a layer of a second ITO layer is plated on a light-emitting quantum dot layer. Most carriers of the first ITO layer and the second ITO layer are different, i.e., carriers in one of the first ITO layer and the second ITO layer are n-type ITO, and carriers in another one of the first ITO layer and the second ITO layer are a p-type ITO. In this way, an ITO-quantum dot-ITO PN junction structure is formed on a single transparent substrate 11. A refractive index of the ITO is similar to a refractive index of the transparent glass flat plate. Moreover, an error of the refractive index of the ITO and the refractive index of the transparent glass flat plate is smaller than or equal to 0.01. An ITO plating manner may be magnetron sputtering, vacuum reaction evaporation, chemical vapor deposition, sol-gel method, and pulsed laser deposition. The magnetron sputtering is preferably performed because the magnetron sputtering is fast in ITO plating speed, compact in film layer, and high in uniformity. One of surfaces of the transparent substrate 11 plated with ITO is spin-coated with a solution where quantum dots are dissolved. Moreover, the quantum dots may be oil-soluble or water-soluble. A thickness of the spin-coated quantum dot layer ranges from 0.05 μm to 10 μm. A spin-coating rotational speed is determined by the required thickness and solution viscosity. According to the method, quantum dots in three light-emitting colors are spin-coated on different substrates, respectively, which are a red-light emitting quantum dot, a green-light emitting quantum dot, and a blue-light emitting quantum dot, respectively.

At S2, a plurality of quantum dot units is bonded.

At S3, the quantum dot complex is obtained by trimming the bonded quantum dot units.

Trimming the bonded quantum dot units may include leveling, curing, trimming, polishing, and the like.

The processing process proposed in the present disclosure can significantly improve uniformity of a light-emitting surface in each layer of a bulk material for three-dimensional display, light-emitting contrast, material transparency, depth resolution, and increase a viewing angle of a three-dimensional image, and the like.

In some embodiments, the plurality of quantum dot units is bonded. The bonding method includes the following steps.

At S21, a spacer is provided on at least one side of each of the plurality of quantum dot units. The spacer is a transparent high polymer material member, a resin member, an optical glass member, or an optical crystal member

In an exemplary embodiment of the present disclosure, the spacer may be in one of a circular truncated cone shape, a cylindrical shape, an elliptical cylindrical shape, a long cylindrical shape, a cuboid shape, a prismatic shape, a spherical shape, and an ellipsoidal shape.

At S22, the plurality of quantum dot units is laminated to form a lamination body. Adjacent ones of the plurality of quantum dot units are spaced apart from each other by the spacer to form a gap for accommodating an adhesive

At S23, two opposite side surfaces of the lamination body are sealed, and another two opposite side surfaces of the lamination body are used as an adhesive introducing surface and an adhesive discharging surface.

At S24, the adhesive is injected to introduce the adhesive from the adhesive introducing surface and fill the gap, to form a layer of cured adhesive containing the spacer between the adjacent quantum dot units.

In some embodiments, the spacer has a height ranging from 1 μm to 500 μm. A distance between adjacent spacers ranges from 0.1 mm to 5 mm. An error on the heights of a plurality of spacers is smaller than or equal to 2 μm. A distribution of the spacer is preferably a matrix distribution. The equal-thickness spacers are discretely formed in a regular array in advance. In this way, after the spacers are laminated, adjacent coating film units are raised by the spacers, so as to form equal-thickness gaps.

Therefore, parallelism of each quantum dot unit is ensured. Moreover, parallelism and flatness of the finally processed quantum dot complex are made better.

A method for arranging the spacer may be any one of the following:

1) A method for printing by spraying a transparent UV adhesive or silk-screen printing. The spacer is made of a material doped with a fast-curing resin. For example, after liquid drops are formed, rapid curing can be performed through UV light, to ensure that the spacers have a same height. The spacer may be in a shape of circle, square, line, or other patterns, preferably a circular dot pattern, from a top view, and the dot diameter ranges from 0.05 mm to 2 mm.

2) A photo-etching or an etching method. A photoresist is coated on a surface to be applied, and exposing, developing, etching, and removing the rest of the photoresist are performed on the surface to be applied. The photoresist is a positive adhesive or a negative adhesive. A photo-etching or etching method is used to manufacture the spacer, which means that the spacer is manufactured directly on the surface to be applied with processed like photoresist coating, exposure, development, etching, residual photoresist removal, and the like. The photoresist used can be a positive adhesive or a negative adhesive. The etching can be performed by wet etching or dry etching. Moreover, the photoresist needs to be spin-coated on a surface that does not need to be etched to perform protection when a photo-etching method is used to manufacture the spacer.

3) Nanoimprint and Nanotransfer Printing

In some embodiments, a distance between adjacent spacers ranges from 5 μm to 20 mm. The spacer is selectable from one of silicon dioxide microsphere, polystyrene microsphere, and polymethyl methacrylate microsphere. The spacer has a spherical diameter ranging from 1 μm to 200 μm. An error on consistency of the diameter is smaller than 10%.

Therefore, by using a size of the spacer, a spacer layer is infiltrated and wrapped with adhesive, and the spacer does not interfere with an optical path.

Further, before sealing or before the adhesive is cured, the method further includes: adjusting parallelism and planeness of the lamination body to control an error on each of the parallelism and the planeness within ±5 μm. Therefore, processing precision of the lamination body is ensured.

In some embodiments, the lamination body is sealed by using a liquid sealant or a solid sealant. The liquid sealant is an epoxy resin or an acrylic resin, and the solid sealant is a rubber plate or a silicone adhesive. The liquid sealant has viscosity greater than 20000 cps, and is hardened through normal-temperature natural hardening, heating hardening, or ultraviolet irradiation hardening. The hardened liquid sealant has shore hardness ranging from 20 A to 70 A. Therefore, a sealing effect on the lamination body is better. Moreover, hardness and strength of a sealant region of the lamination body are ensured.

Further, the adhesive is defoamed before being injected. The adhesive has viscosity smaller than 500 cps. The adhesive is an epoxy resin or an acrylic resin. The cured adhesive has a volume shrinkage rate smaller than 1.1%, shore hardness ranging from 60 D to 80 D, and a refractive index same as a refractive index of the transparent substrate. In this way, by using the above adhesive, an adhesive effect is better.

In some embodiments, the adhesive is injected through one of a first gravity injection, a second gravity injection, a first pressure injection, a second pressure injection, and a vacuum injection. The first gravity injection includes: placing the adhesive introducing surface of the lamination body in an adhesive pool of a gravity adhesive feeding device; connecting sealingly the gravity adhesive feeding device and the adhesive introducing surface through a sealing material or a sealing tool; placing the lamination body and the adhesive feeding device into a vacuum chamber of a vacuum device; filling the gap with the adhesive through gravity of the adhesive and a capillary of the adhesive; closing the vacuum device in response to observing the adhesive uniformly seeps at all positions of the adhesive discharging surface; and completing the injection of the adhesive. The second gravity injection includes: placing the adhesive introducing surface of the lamination body in an adhesive pool of a gravity adhesive feeding device; connecting sealingly the gravity adhesive feeding device and the adhesive introducing surface through a sealing material or a sealing tool; connecting a vacuum device at the adhesive discharging surface to wrap the entire adhesive discharging surface of the lamination body; isolating the adhesive discharging surface from external environment through the sealing material or the sealing tool; setting an absolute vacuum degree of the vacuum device to be smaller than 10 kpa; closing the vacuum device in response to observing the adhesive uniformly seeps at all positions of the adhesive discharging surface; and completing the injection of the adhesive. The first pressure injection includes: placing the adhesive introducing surface of the lamination body in an adhesive of a pressure adhesive feeding device; connecting sealingly the pressure adhesive feeding device and the adhesive introducing surface through a sealing material or a sealing tool; applying a mechanical pressure to allow the gap to be full of the adhesive; monitoring an adjustment pressure by a pressure sensor mounted at the pressure adhesive feeding device to control an adhesive feeding speed; closing a pressure applying device in response to observing the adhesive uniformly seeps at all positions of the adhesive discharging surface; and completing the injection of the adhesive. The second pressure injection includes: placing the adhesive introducing surface of the lamination body in an adhesive of a pressure adhesive feeding device; connecting sealingly the pressure adhesive feeding device and the adhesive introducing surface through a sealing material or a sealing tool; applying an atmospheric pressure to allow the gap to be full of the adhesive; monitoring an adjustment air pressure by a gas flow valve mounted at the pressure adhesive feeding device to control an adhesive feeding speed; closing a pressure applying device in response to observing the adhesive uniformly seeps at all positions of the adhesive discharging surface; and completing the injection of the adhesive. The vacuum injection includes: immersing the adhesive introducing surface of the lamination body in an adhesive pool containing the adhesive to liquid-seal the entire adhesive introducing surface by the adhesive; connecting a vacuum device at the adhesive discharging surface to wrap the entire adhesive discharging surface of the lamination body by the vacuum device; isolating the adhesive discharging surface from an external environment through a sealing material or a sealing tool; setting an absolute vacuum degree of the vacuum device smaller than 10 kpa; closing the vacuum device in response to observing the adhesive uniformly seeps at all positions of the adhesive discharging surface; and completing the injection of the adhesive.

Therefore, by injecting the adhesive in the above manners, adhesive efficiency is higher.

In some embodiments, the plurality of quantum dot units is bonded, and the bonding method includes the following steps.

At S25, after a first quantum dot unit is coated with the adhesive, a second quantum dot unit is placed on the adhesive 60 for bonding, and this process is repeated to form a laminated structure.

At S26, parallelism and flatness of the laminated structure prior to curing the laminated structure are adjusted.

In this way, there is no need to provide a spacer. By adopting a spin coating lamination manner, a spacing between adjacent quantum dot units is smaller. Therefore, the influence on the optical path is smaller.

In some embodiments, the adhesive preferably has viscosity smaller than 1000 cps. The adhesive is an epoxy resin or an acrylic resin. The cured adhesive has a volume shrinkage rate smaller than 1.1% and shore hardness ranging from 60D to 80D. Therefore, the above adhesive is determined in the above lamination and bonding manner, and the adhesive effect is better.

In an exemplary embodiment of the present disclosure, processing the plurality of quantum dot units includes the following steps.

At S11, a first photoresist layer is coated at a side of the transparent substrate.

At S12, exposing and developing are performed to retain a part of the first photoresist layer to form a first residue portion.

At S13, the first transparent conductive layer is plated at an exposure and development side of the transparent substrate.

At S14, the first residue portion is peeled to form a first protrusion on the first transparent conductive layer. The first protrusion is located at a side of a peeling region, and configured to be connected to a first electrode.

At S15, the quantum dot layer is coated at a side where the first transparent conductive layer is located.

At S16, a second photoresist layer is coated.

At S17, exposing and developing are performed to retain a part of the second photoresist layer to form a second residue portion. The second residue portion and the first residue portion are arranged close to an edge of the transparent substrate.

At S18, the second transparent conductive layer is plated at the exposure and development side of the transparent substrate.

At S19, the second residual portion is peeled to form a second protrusion on the second transparent conductive layer. The second protrusion is located at a side of the second residual portion, and configured to be connected to a second electrode. The first protrusion is offset from the second protrusion.

Therefore, a quantum body unit layer forms the transparent conductive layer in a manner of plating the first transparent conductive layer and the second transparent conductive layer, to realize independent application of an electric field of each quantum body unit layer. In this way, independent display of each quantum body unit layer can be realized.

A processing method for a three-dimensional display element according to embodiments of a second aspect of the present disclosure includes: the process for the quantum dot complex according to the above embodiments; providing a first electrode and a second electrode, in which the first electrode is electrically connected to a first transparent conductive layer of each quantum dot unit, and the second electrode is electrically connected to a second transparent conductive layer of each quantum dot unit; and attaching a circuit board to a side of the quantum dot complex, and connecting the circuit board to the first electrode and the second electrode.

In this way, the first electrode and the second electrode are connected to the circuit, allowing the quantum dots to have high photoluminescence quantum efficiency in a case where no electric field is added. After a predetermined electric field is applied, the photoluminescence quantum efficiency is lowered and even close to zero. In addition, photons absorbed by the quantum dots are almost emitted in a non-radiation relaxation manner. After the electric field is removed, light-emitting efficiency of the quantum dots can also be restored to the initial state.

A quantum dot complex 100 according to embodiments of a third aspect of the present disclosure includes: a plurality of quantum dot units 10 sequentially laminated and bonded to each other in a thickness direction. Each of the plurality of quantum dot units 10 includes a transparent substrate 11, a first transparent conductive layer, a second transparent conductive layer, a quantum dot layer 13. The first transparent conductive layer and the quantum dot layer 13 are located at a side of the transparent substrate 11 and sequentially arranged away from the transparent substrate 11. The second transparent conductive layer is located at another side of the transparent substrate 11 or located outside the quantum dot layer 13. One of the first transparent conductive layer 12 and the second transparent conductive layer 14 is a P-type semiconductor, and another one of the first transparent conductive layer 12 and the second transparent conductive layer 14 is an N-type semiconductor. The quantum dot layer 13, the first transparent conductive layer, and the second transparent conductive layer of a quantum dot unit 10 where the first transparent conductive layer 13 is located or of a quantum dot unit 10 adjacent to the quantum dot unit 10 where the first transparent conductive layer 13 is located are formed as a PN junction.

The present disclosure provides a novel quantum dot complex 100. In an exemplary embodiment of the present disclosure, a bulk structure having a multi-layer multicolor light-emitting quantum dot unit 10 is manufactured by using an effect of a reduction in the light-emitting efficiency of the photoluminescence quantum dots under modulation of the electric field through a technology of compounding the quantum dot, the transparent conductive material, and other transparent materials. Then, a three-dimensional pattern is scanned in the bulk structure by using a laser scanning system and an electric field modulation system.

In the case where no electric field is added, the quantum dots have higher photoluminescence quantum efficiency. After a predetermined electric field is applied, the photoluminescence quantum efficiency is lowered and even close to zero. Moreover, the photons absorbed by the quantum dots are almost emitted in the non-radiation relaxation mode. After the electric field is removed, the light-emitting efficiency of the quantum dots can also be restored to the initial state. This characteristic of the quantum dot is referred to as a switching effect of quantum dot electric field modulation. In a case where an excitation light parameter is kept unchanged, a ratio of a light-emitting intensity of the quantum dot without adding the electric field to a light-emitting intensity of the quantum dot with the electric field is a switching ratio. The switching ratio is preferably greater than 20.

In order to ensure that under the same condition, brightness of light-emitting points in front of a laser incident surface of the bulk material is the same as brightness of light-emitting points in back of the laser incident surface of the bulk material. In this way, an energy loss problem of a laser passing through the quantum dot unit 10 is counteracted. Therefore, thicknesses of the quantum dot units 10 of the laser incident surface of the bulk material are required to be gradually increased from front to back. In other words, a side surface of the quantum dot complex 100 is formed as a laser incident surface. In a lamination direction of the quantum dot units 10, the greater a distance from the laser incident surface, the greater a thickness of the quantum dot unit 10.

In some embodiments, the quantum dot layer 13 has a thickness ranging from 0.05 μm to 10 μm; and/or the transparent substrate 11 has a thickness ranging from 0.1 mm to 0.5 mm. An error of parallelism and planeness of each of an upper smooth surface and a lower smooth surface of the transparent substrate 11 is smaller than or equal to ±2 μm. A length a and a width b of the transparent substrate 11 satisfy 1 mm≤a≤500 mm, and 1 mm≤b≤500 mm. Therefore, the quantum dot layer 13 uses the above size. Moreover, the manufactured quantum dot complex 100 is more compact in structure.

In another exemplary embodiment of the present disclosure, a quantum dot layer 13 of each quantum dot unit 10 is configured to emit light in one color when being irradiated. A structure of a quantum dot complex 100 monochromatically displayed is that light-emitting layer units of single-color emission quantum dots are periodically arranged. Moreover, the layer units and the layer units are bonded to each other by a transparent adhesive. Electrodes are manufactured on both surfaces of each layer of quantum dot layer 13 and have the function of applying an electric field with an adjustable size and direction to the quantum dots.

In another exemplary embodiment of the present disclosure, every three adjacent quantum dot units 10 are defined as a color adjustment group. Quantum dot layers 13 of three quantum dot units 10 in each color adjustment group are configured to respectively emit red light, green light, and blue light when being irradiated. For example, an arrangement rule of the unit layer is: a red-light emitting quantum dot unit 10, a green-light emitting quantum dot unit 10, and a blue-light emitting quantum dot unit 10. The quantum dot units 10 in three colors are periodically arranged. The unit layer and the unit layer are bonded to each other through the transparent adhesive. The two surfaces of each quantum dot unit 10 are manufactured with transparent electrodes, which have the function of applying the electric field with the adjustable size and direction to the quantum dots.

A three-dimensional display element according to embodiments of a fourth aspect of the present disclosure includes: the quantum dot complex 100 according to the above embodiments and a circuit board. The circuit board is electrically connected to a first transparent conductive layer 12 and a second transparent conductive layer 14 of each quantum dot unit 10 by a first electrode and a second electrode, respectively.

Compared with three-dimensional display of liquid crystal lamination, a three-dimensional display element modulated by the electric field and a light field has the following advantages.

First, an image frame rate is higher. A modulation time of quantum dot screen modulated by a single-layer electric field is smaller than 10 μs, while a single refresh time of the liquid crystal layer is an ms level.

Second, three-dimensional imaging longitudinal resolution is higher. Resolution of the liquid crystal layer in a three-dimensional display depth direction is limited since a refresh speed of the liquid crystal layer is slow. For example, when the refresh speed of the liquid crystal layer is 1 ms, it is calculated that according to a human eye visual persistence effect being 25 Hz, a maximum lamination number of the liquid crystal layer is 40 layers. Frame frequency must be sacrificed if more layers want to be laminated. A modulation time of the quantum dot screen modulated by the single-layer electric field is smaller than 10 μs. Moreover, it is calculated that 4000 layers can be laminated with 10 μs and 25 Hz

Third, a viewing angle is greater. Due to the limitation of a frame of the liquid crystal screen, a viewing angle of the three-dimensional display of the liquid crystal layer is limited to a small angle on a front surface, and a side surface and a back surface of the liquid crystal layer cannot be viewed. In addition, the image cannot be viewed in a small region of a surface of an electrode arrangement of a three-dimensional display system based on dual modulation of the light field and the electric field. Except for this, viewing can be performed in the rest of directions.

Fourth, a color gamut is higher. A light source used by a three-dimensional display system of the liquid crystal lamination is LED backlight. However, the three-dimensional display system based on the dual modulation of the light field and the electric field adopts photoluminescence quantum dots. It is well known that the quantum dots have a higher color gamut than the LED

A manufacturing process flow of the quantum dot complex 100 in two specific embodiments is briefly described below.

First Embodiment: A siphon method is used for manufacturing the quantum dot complex 100.

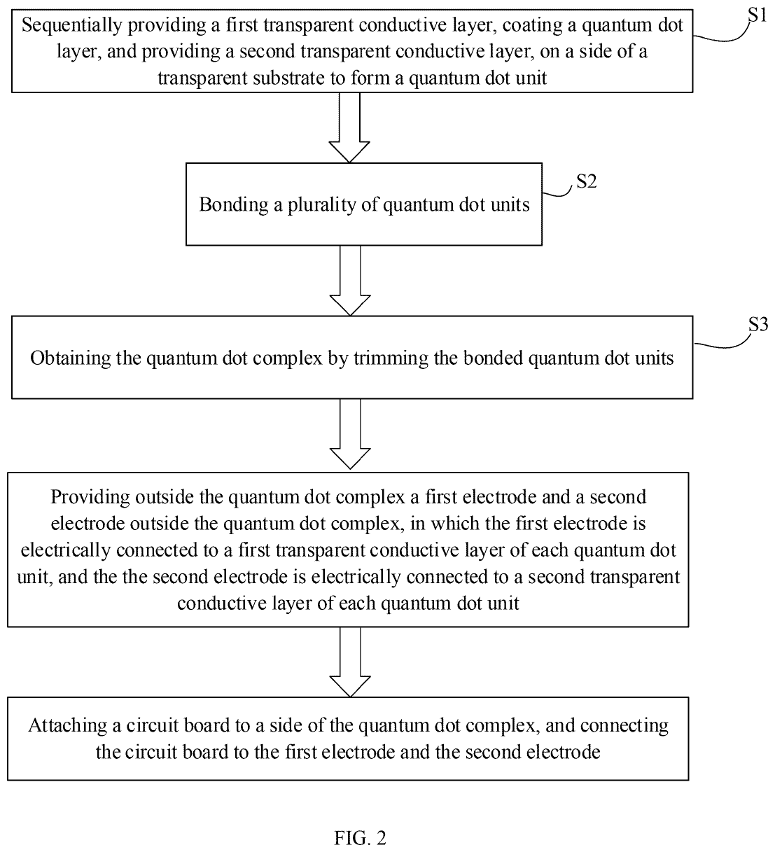

FIG. 2 is a process flow of manufacturing a quantum dot complex 100 according to an embodiment.

1) Preparation of the Transparent Substrate 11

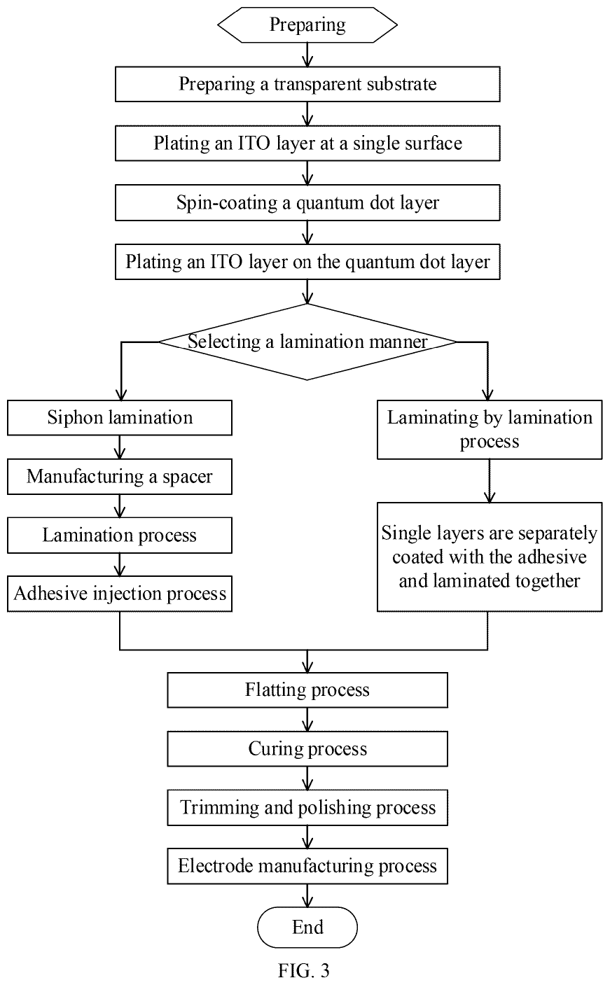

FIG. 3 is an ultra-thin glass flat plate manufactured by a transparent base material selecting a process such as a float method, an overflow stretching method, a slit stretching method, and a secondary stretching method. A thickness of a base material ranges from 0.1 mm to 5 mm. Surface type detection is performed on the glass flat plate, to ensured that an error of parallelism and planeness of each of an upper smooth surface and a lower smooth surface of the transparent substrate is smaller than or equal to ±2 μm. A length a and a width b of a glass unit are preferably in a range of: 1 mm≤a≤500 mm, and 1 mm≤b≤500 mm. In addition, a resin transparent plate may also be selected as the base material.

2) Quantum Dot Application Process

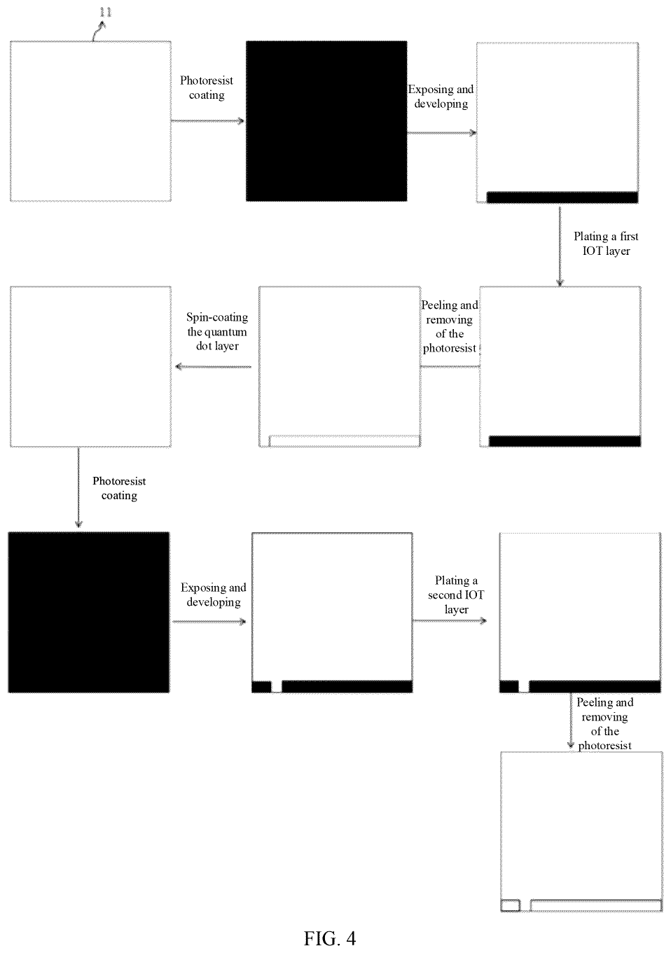

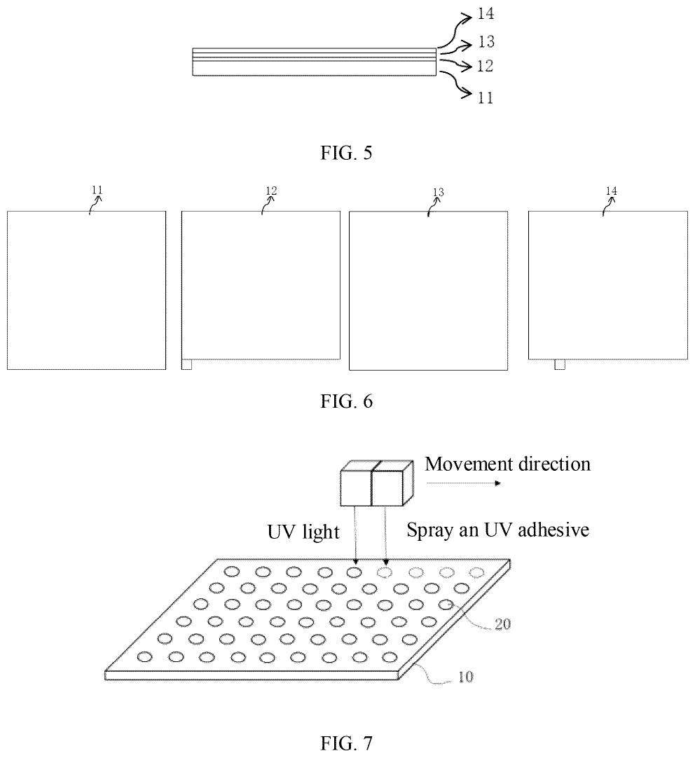

FIG. 4 shows a structure processing process of a single-layer quantum dot unit 10. FIG. 5 shows a shape feature of a structure in each layer. The transparent substrate 11 is transparent glass. A layer of a first ITO layer 12 is plated on the transparent substrate 11. A layer of light-emitting quantum dots 13 is spin-coated on the first ITO layer 12. Finally, a layer of a second ITO layer 14 is plated on the quantum dot layer 13 again. Most carriers of the first ITO layer and the second ITO layer are different, i.e., carriers in one of the first ITO layer and the second ITO layer are n-type ITO, and carriers in another one of the first ITO layer and the second ITO layer are a p-type ITO. In this way, an ITO-quantum dot-ITO PN junction structure is formed on a single transparent substrate 11. A refractive index of the ITO is similar to a refractive index of the transparent glass flat plate. Moreover, an error of the refractive index of the ITO and the refractive index of the transparent glass flat plate is smaller than or equal to 0.01. An ITO plating manner may be magnetron sputtering, vacuum reaction evaporation, chemical vapor deposition, sol-gel method, and pulsed laser deposition. The magnetron sputtering is preferably performed because the magnetron sputtering is fast in ITO plating speed, compact in film layer, and high in uniformity. One of surfaces of the transparent substrate 11 plated with ITO is spin-coated with a solution where quantum dots are dissolved. Moreover, the quantum dots may be oil-soluble or water-soluble. A thickness of the spin-coated quantum dot layer 10 ranges from 0.05 μm to 10 μm. A spin-coating rotational speed is determined by the required thickness and solution viscosity. According to the method, quantum dots in three light-emitting colors are spin-coated on different substrates, respectively, which are a red-light emitting quantum dot, a green-light emitting quantum dot, and a blue-light emitting quantum dot, respectively.

In addition, N-type ITO may also select other N-type transparent semiconductor materials, and P-type ITO may also select other P-type transparent semiconductor materials.

In order to ensure that under the same condition, brightness of light-emitting points in front of a laser incident surface of the bulk material is the same as brightness of light-emitting points in back of the laser incident surface of the bulk material. In this way, an energy loss problem of a laser passing through the quantum dot unit 10 is counteracted. Therefore, thicknesses of the quantum dot layers 13 of the laser incident surface of the bulk material are required to be gradually increased from front to back.

3) Manufacture of the Spacers 20

A forming step of the spacer 20 is that the equal-thickness spacers 20 are discretely formed in a regular array in advance. In this way, after the spacers are laminated, adjacent coating film units are raised by the spacers 20, so as to form equal-thickness gaps.

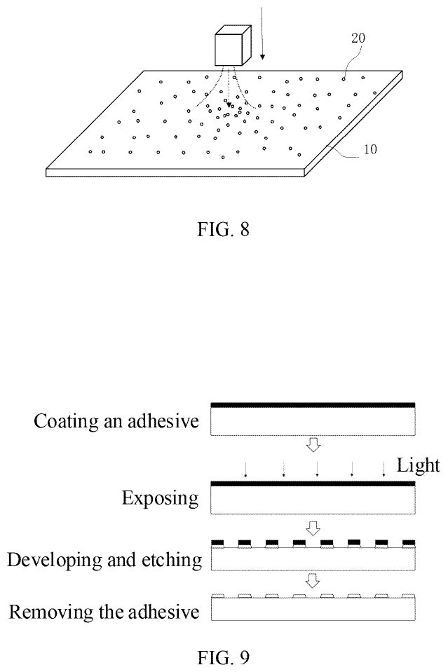

The spacer 20 may be formed by printing by spraying the transparent UV adhesive (FIG. 7), silk-screen printing, a photolithography-etching method (FIG. 8), nanoimprint, and nanotransfer printing, and the like. The spacer has a height ranging from 1 μm to 500 μm. A distance between adjacent spacers ranges from 0.1 mm to 5 mm. An error on the heights of a plurality of spacers is smaller than or equal to 2 μm. A distribution of the spacer 20 is preferably a matrix distribution.

When the spacer 20 is manufactured through printing by spraying the transparent UV adhesive (FIG. 7) or silk-screen printing, the spacer 20 is made of a material doped with a fast-curing resin. For example, after liquid drops are formed, rapid curing can be performed through UV light, to ensure that the spacers 20 have a same height. The spacer 20 may be in a shape of circle, square, line, or other patterns, preferably a circular dot pattern, from a top view, and the dot diameter ranges from 0.05 mm to 2 mm.

The spacer 20 is fabricated by the photo-etching method or the etching method (FIG. 8), which means that the spacer 20 is manufactured directly on the surface to be applied with photoresist coating, exposure, development, etching, residual photoresist removal, and the like. The photoresist used can be a positive adhesive or a negative adhesive. The etching can be performed by wet etching or dry etching. Moreover, the photoresist needs to be spin-coated on a surface that does not need to be etched to perform protection when a photo-etching method is used to manufacture the spacer 20.

In addition, other granular materials with uniform sizes may also be used as spacers 20, and are uniformly dispersed between two layers of substrate units spin-coated with the light-emitting quantum dots. A distance between two adjacent particles is D, where D satisfies 5 μm≤D≤20 mm. A contour dimension of the spacer 20 may satisfy in any one of a circular truncated cone shape, a cylindrical shape, an elliptical cylindrical shape, a long cylindrical shape, a cuboid shape, a prismatic shape, a spherical shape, and an ellipsoidal shape. A spherical shape, a diameter ranging from 1 μm to 200 μm, and an error on consistency of the diameter smaller than 10% are preferred. An application manner of the spacer 20 is a method for spraying a microsphere spacer (FIG. 9). The microsphere spacer 20 may be silicon dioxide microsphere, polystyrene microsphere, and polymethyl methacrylate microsphere. In addition, the granular spacer 20 may also be a high polymer material member, a resin member, an optical glass member or an optical crystal member.

4) As illustrated in FIG. 10, lamination is performed on the transparent substrate 11 that makes the spacer 20.

For full-color imaging, a lamination rule is that: \textcircled{1} quantum dot units 10 in each layer have the same direction; and \textcircled{2} an arrangement rule of periodically arranging the quantum dot light-emitting layer units in three colors including the red-light emitting quantum dot unit 10, the green-light emitting quantum dot unit 10, and the blue-light emitting quantum dot unit 10.

For monochromatic imaging, a lamination rule is \textcircled{1} using a quantum dot light-emitting layer in a color to laminate; and \textcircled{2} that quantum dot units 10 in each layer have the same direction.

5) Parallelism and planeness of the lamination body are adjusted. As illustrated in FIG. 11, the laminated lamination body is clamped by the rigid plate body 40 or a gasbag. Moreover, parallelism and planeness of each of a unit at an uppermost layer and a unit at a lowermost layer are adjusted through a parallelism adjustment device. In this way, by assuming that an error on each of the parallelism and the planeness is controlled within ±5 μm, the accumulated error of the parallelism and flatness caused by unequal thickness of each of the spacer 20, the transparent substrate 11, and the spin-coated quantum dot layer 13 in each layer of unit are corrected. The process may also be performed after the adhesive is injected and before the adhesive 60 is cured.

6) Sealing Process

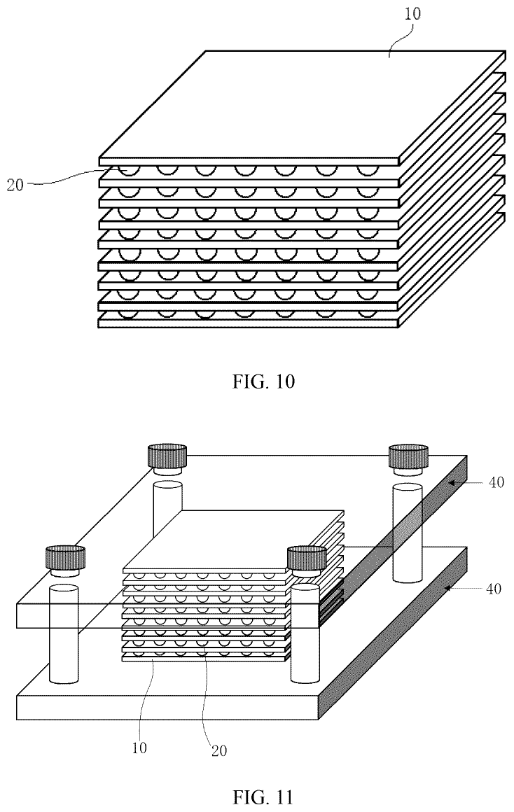

Two opposite surfaces among four surfaces of the lamination body perpendicular to a lamination direction are selected as sealing surfaces, and a sealant 30 is used to seal the sealing surface. As illustrated in FIG. 12, the sealant 30 is a solid sealing material or a liquid sealing material. When the liquid sealant 30 is the liquid sealing material and has viscosity greater than 20000 cps, the liquid sealant 30 is made of an epoxy resin or an acrylic resin, and is hardened through normal-temperature natural hardening, heating hardening, or ultraviolet irradiation hardening. The hardened liquid sealant has shore hardness ranging from 20 A to 70 A. When the liquid sealant 30 is the solid sealing material, a rubber plate or a silicone adhesive with good ductility can be selected. A sealing effect can also be achieved by tightly pressing and attaching the sealing surface through a sealing tool.

7) Adhesive Injection Process

One of another two opposite surfaces among four surfaces of the lamination body parallel to the lamination direction is selected as the adhesive introducing surface, and another one of the other two opposite surfaces is used as the adhesive discharging surface. A curing adhesive 60 enters a spacer layer in a middle of the substrate unit from the adhesive introducing surface and is led out from the adhesive discharging surface. In this way, each spacer layer is filled with the adhesive 60 uniformly to complete injection. The injected adhesive 60 has viscosity smaller than 500 cps preferably and is cured through heating curing or normal-temperature natural curing. The adhesive 60 is an epoxy resin or an acrylic resin. The cured adhesive 60 preferably has a volume shrinkage rate smaller than 1.1% and shore hardness ranging from 60 D to 80 D. The adhesive 60 is defoamed before being injected. The color of the adhesive 60 is preferably transparent. An error between a refractive index of the cured adhesive 60 and a refractive index of the transparent substrate 11 is smaller than 0.01.

The adhesive injection method includes gravity injection, pressure injection, and vacuum injection.

A first gravity injection 1 is provided. The adhesive introducing surface of the lamination body is placed in a gravity adhesive feeding device, i.e., an adhesive. As illustrated in FIG. 13, a sealing connection between the gravity adhesive feeding device and the adhesive introducing surface is carried out through a sealing material or a sealing tool. The lamination body and the adhesive feeding device are placed into a vacuum chamber 52 of a vacuum device. A gap layer is filled with bonding glue a through gravity of the adhesive and a capillary of the adhesive. The vacuum device may be closed in response to observing the adhesive 60 uniformly seeps at all positions of the adhesive discharging surface, and completing the injection of the adhesive 60.

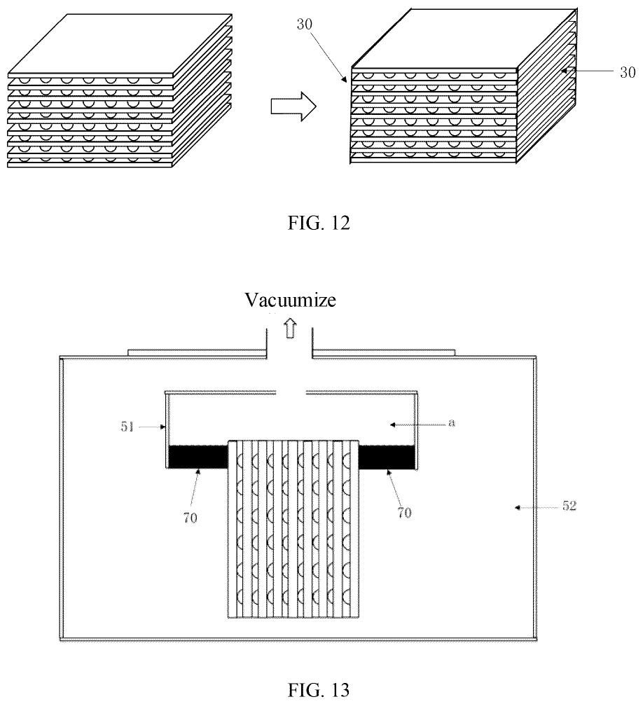

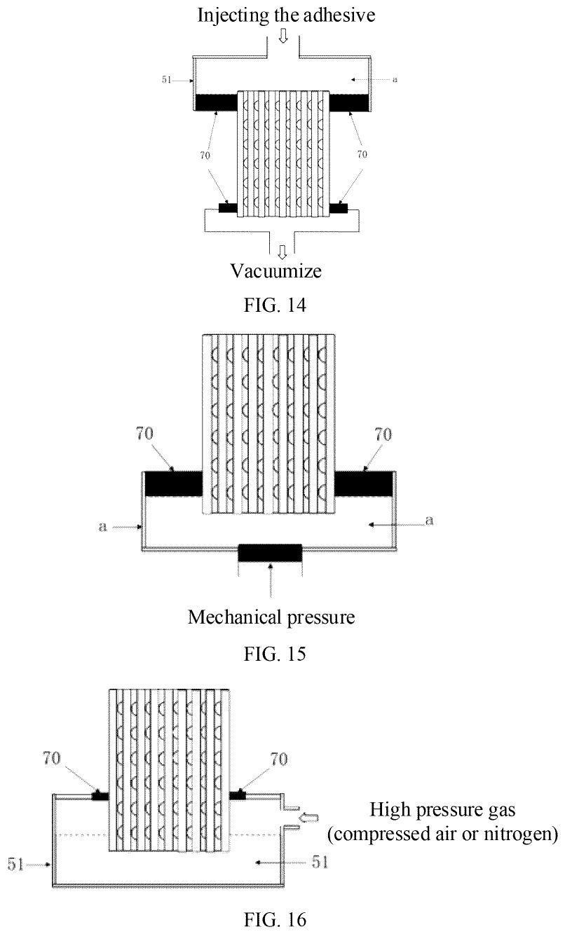

A second gravity injection 2 includes placing the adhesive introducing surface of the lamination body in an adhesive pool of a gravity adhesive feeding device. As illustrated in FIG. 14, a sealing connection between the gravity adhesive feeding device and the adhesive introducing surface is carried out through a sealing material or a sealing tool. Then, a vacuum device is connected at the adhesive discharging surface to wrap the entire adhesive discharging surface of the lamination body. Moreover, the adhesive discharging surface is isolated from an external environment through the sealing material or the sealing tool, to ensure that no air leakage phenomenon occurs during vacuumizing. An absolute vacuum degree of the vacuum device is set to be smaller than 10 kpa preferably. The vacuum device may be closed in response to observing the adhesive 60 uniformly seeps at all positions of the adhesive discharging surface, and completing adhesive 60 injection.

A first pressure injection 1 includes placing the adhesive introducing surface of the lamination body in an adhesive of a pressure adhesive feeding device. As illustrated in FIG. 15, a sealing connection between the pressure adhesive feeding device and the adhesive introducing surface is carried out through a sealing material or a sealing tool. A mechanical pressure is applied to allow the gap to be full of the adhesive. An adjustment pressure is monitored by a pressure sensor mounted at the pressure adhesive feeding device to control an adhesive feeding speed. A pressure applying device may be closed in response to observing the adhesive 60 uniformly seeps at all positions of the adhesive discharging surface, and completing adhesive 60 injection.

As illustrated in FIG. 16, a second pressure injection 2 includes: placing the adhesive introducing surface of the lamination body in an adhesive of a pressure adhesive feeding device, connecting sealingly the pressure adhesive feeding device and the adhesive introducing surface through a sealing material or a sealing tool, applying an atmospheric pressure to allow the gap to be full of the adhesive, and monitoring an adjustment air pressure by a gas flow valve mounted at the pressure adhesive feeding device to control an adhesive feeding speed. In addition, a pressure applying device may be closed in response to observing the adhesive 60 uniformly seeps at all positions of the adhesive discharging surface, and completing adhesive 60 injection.

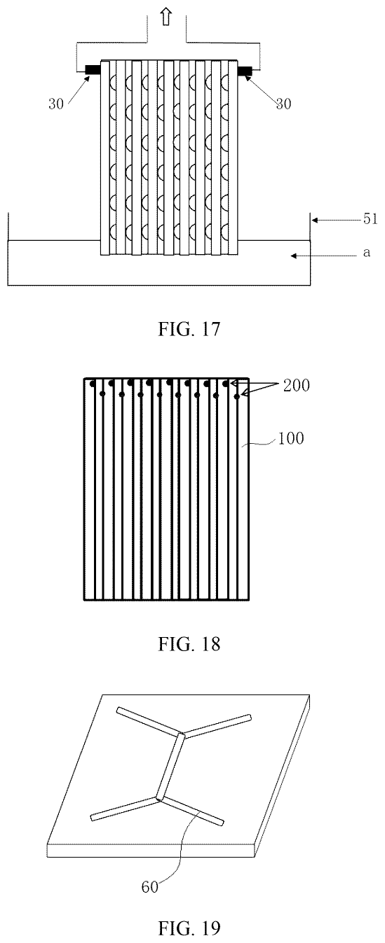

As illustrated in FIG. 17, a vacuum injection includes: immersing the adhesive introducing surface of the lamination body in an adhesive pool 51 containing the adhesive 60 to liquid-seal the entire adhesive introducing surface by the adhesive 60. Then, a vacuum device is connected at the adhesive discharging surface to wrap the entire adhesive discharging surface of the lamination body by the vacuum device. Moreover, the adhesive discharging surface is isolated from an external environment through a sealing material or a sealing tool, to ensure that no air leakage phenomenon occurs during vacuumizing. An absolute vacuum degree of the vacuum device is set to be smaller than 10 kpa. The vacuum device may be closed in response to observing the adhesive 60 uniformly seeps at all positions of the adhesive discharging surface, and completing adhesive 60 injection.

8) Curing and Heat Treatment Processes

After the injection of the adhesive 60 is completed, the adhesive 60 can be cured by heating for a period of time or through constant-temperature placement for a period of time. Moreover, internal stress is eliminated in a necessary heat treatment manner to obtain a lamination block. Before curing, parallelism and planeness of each of a coating film unit at an uppermost layer of the lamination block and a coating film unit at a lowermost of the lamination block can be corrected through the parallelism adjustment device. For example, the lamination block can be laminated and engaged by using a precision hydraulic device, with a pressing force greater than or equal to 20 kPa. The lamination block is corrected through the parallelism and planeness of an operation surface of a press machine. Moreover, the correction of the lamination block is continuously kept until the adhesive 60 is cured.

9) A trimming and polishing process. Trimming and polishing processes are performed on the cured lamination block sequentially. A trimming purpose is processing the lamination block into an approximately standard cube, and then polishing each surface of the lamination block, allowing the lamination body to maintain high light transmittance and prepare for the next process.

10) The manufacture of the electrode 20. The electrode 20 is manufactured by selecting one of the four surfaces of the lamination body perpendicular to the lamination direction to be photolithographed and coated. The electrode 20 is introduced into each layer of ITO. As illustrated in FIG. 18, it is ensured that no short circuit exists between the ITO layer and the layer. The electrode 20 may be made of gold or silver, preferably the gold.

11) An attaching printed circuit board and a welding wire. The circuit board manufactured as specifications is attached to a surface of the manufactured electrode 20. Moreover, the electrode 20 on the laminated body is connected to the attaching printed circuit board by using an ultrasonic wire welding machine. In order to achieve a greater viewing angle, it is preferable to make the electrode 20 on one surface. A voltage is applied to the ITO layer at both sides of the quantum dot layer 13 through a control system. The light-emitting efficiency of the quantum dots in the electric field decreases to near zero under the action of the electric field. Moreover, the full-color three-dimensional display can be achieved by controlling a magnitude of the applied electric field and the quantum dots in three colors including red, green, and blue.

Second Embodiment: The lamination material is manufactured by the lamination method.

Lamination processes are performed on the unit layer that completes the process of FIG. 5.

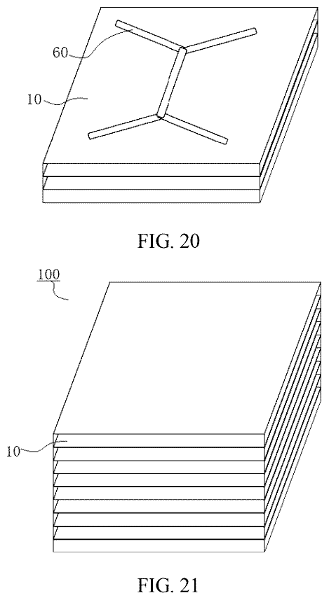

The lamination process is as follows. As illustrated in FIG. 19, FIG. 20, and FIG. 21, a flat plate for completing the process of FIG. 5 is taken and placed on a flat plate tool. An upward surface of the flat plate is coated with an “I”-shaped adhesive 60. Then, a flat plate for completing the process of FIG. 5 is taken and placed on the adhesive 60, and has a same direction as the quantum dot unit 10 on the first flat plate, i.e., the quantum dot units 10 are both upwards or downwards. The adhesive 60 preferably has viscosity smaller than 1000 cps, and is cured through heating curing or normal-temperature natural curing. The adhesive 60 is an epoxy resin or an acrylic resin. Preferably, the cured adhesive 60 has a volume shrinkage rate smaller than 1.1%, shore hardness ranging from 60 D to 80 D. The adhesive 60 is defoamed before being injected. The color of the adhesive 60 is preferably transparent. A refractive index of the cured adhesive 60 is similar to a refractive index of the transparent substrate 11. An error between the refractive index of the cured adhesive 60 and the refractive index of the transparent substrate 11 is smaller than 0.01.

For full-color imaging, a lamination rule is that: \textcircled{1} quantum dot units 10 in each layer have the same direction; and \textcircled{2} an arrangement rule of periodically arranging the quantum dot light-emitting layer units 10 in three colors including the red-light emitting quantum dot unit 10, the green-light emitting quantum dot unit 10, and the blue-light emitting quantum dot unit 10.

For monochromatic imaging, a lamination rule is \textcircled{1} using a quantum dot light-emitting layer in a color to laminate; and \textcircled{2} that quantum dot units 10 in each layer have the same direction.

5) Parallelism and planeness of the lamination body are adjusted. Parallelism and planeness of each of a unit at an uppermost layer and a unit at a lowermost layer are adjusted through a parallelism adjustment device. In this way, by assuming that an error on each of the parallelism and the planeness is controlled within ±5 μm, the accumulated error of the parallelism and flatness caused by unequal thickness of each of the spacer 20, the transparent substrate 11, and the spin-coated quantum dot layer 13 in each layer of unit are corrected. The process may also be performed after the adhesive is injected and before the adhesive 60 is cured.

6) Curing and Heat Treatment Processes

After the injection of the adhesive 60 is completed, the adhesive 60 can be cured by heating for a period of time or through constant-temperature placement for a period of time. Moreover, internal stress is eliminated in a necessary heat treatment manner to obtain a lamination block.

7) A trimming and polishing process. Trimming and polishing processes are performed on the cured lamination block sequentially. A trimming purpose is processing the lamination block into an approximately standard cube, and then polishing each surface of the lamination block, allowing the lamination body to maintain high light transmittance and prepare for the next process.

8) The manufacture of the electrode 20. The electrode 20 is manufactured by selecting one of the four surfaces of the lamination body perpendicular to the lamination direction to be photolithographed and coated. The electrode 20 is introduced into each layer of ITO. Moreover, it is ensured that no short circuit exists between the ITO layer and the layer. The electrode 20 may be made of gold or silver, preferably the gold.

9) An attaching printed circuit board and a welding wire. The circuit board manufactured as specifications is attached to a surface of the manufactured electrode 20. Moreover, the electrode 20 on the laminated body is connected to the attaching printed circuit board by using an ultrasonic wire welding machine. In order to achieve a greater viewing angle, it is preferable to make the electrode 20 at an edge close to the bulk material.

In the description of the present disclosure, it should be understood that, the orientation or the position indicated by technical terms such as “center”, “longitudinal”, “lateral”, “length”, “width”, “thickness”, “over”, “below”, “front”, “rear”, “left”, “right”, “vertical”, “horizontal”, “top”, “bottom”, “inner”, “outer”, “clockwise”, “anti-clockwise”, “axial”, “radial”, and “circumferential” should be construed to refer to the orientation and the position as shown in the drawings, and is only for the convenience of describing the present disclosure and simplifying the description, rather than indicating or implying that the pointed device or element must have a specific orientation, or be constructed and operated in a specific orientation, and therefore cannot be understood as a limitation on the present disclosure.

In the description of the present disclosure, “the first feature” and “the second feature” may include at least one of the features. In the description of the present disclosure, “plurality” means at least two. In the description of the present disclosure, the first feature being “on” or “under” the second feature may include the scenarios that the first feature is in direct contact with the second feature, or the first and second features, instead of being in direct contact with each other, are in contact with each other through another feature therebetween. In the description of the present disclosure, the first feature being “above” the second feature may indicate that the first feature is directly above or obliquely above the second feature, or simply indicate that the level of the first feature is higher than that of the second feature.

In the description of this specification, descriptions with reference to the terms “an embodiment,” “some embodiments,” “schematic embodiments,” “examples,” “specific examples,” or “some examples,” etc. mean that specific features, structure, materials or characteristics described in conjunction with the embodiment or example are included in at least one embodiment or example of the present disclosure. In this specification, the schematic representations of the above terms do not necessarily refer to the same embodiment or example.

Although embodiments of the present disclosure have been illustrated and described, it is conceivable for those of ordinary skilled in the art that various changes, modifications, replacements, and variations can be made to these embodiments without departing from the principles and spirit of the present disclosure. The scope of the present disclosure shall be defined by the claims as appended and their equivalents.

What is claimed is:

1. A process for a quantum dot complex, comprising:
sequentially providing a first transparent conductive layer, coating a quantum dot layer, and providing a second transparent conductive layer, on a side of a transparent substrate to form a quantum dot unit;
bonding a plurality of quantum dot units; and
obtaining the quantum dot complex by trimming the bonded quantum dot units.

2. The process according to claim 1, wherein said bonding the plurality of quantum dot units comprises:
providing a spacer on at least one side of each of the plurality of quantum dot units, wherein the spacer is a transparent high polymer material member, a resin member, an optical glass member, or an optical crystal member;
laminating the plurality of quantum dot units to form a lamination body, wherein adjacent ones of the plurality of quantum dot units are spaced apart from each other by the spacer to form a gap for accommodating an adhesive;
sealing two opposite side surfaces of the lamination body, and using another two opposite side surfaces of the lamination body as an adhesive introducing surface and an adhesive discharging surface; and
injecting the adhesive to introduce the adhesive from the adhesive introducing surface and fill the gap, to form a layer of cured adhesive containing the spacer between the adjacent quantum dot units.

3. The process according to claim 2, wherein the spacer has a height ranging from 1 μm to 500 μm;
a distance between adjacent spacers ranges from 0.1 mm to 5 mm; and
an error on the heights of a plurality of spacers is smaller than or equal to 2 μm.

4. The process according to claim 2, wherein a distance between adjacent spacers ranges from 5 μm to 20 mm;
the spacer is selectable from one of silicon dioxide microsphere, polystyrene microsphere, and polymethyl methacrylate microsphere; and
the spacer has a spherical diameter ranging from 1 μm to 200 μm, an error on consistency of the diameter being smaller than 10%.

5. The process according to claim 2, further comprising, prior to sealing the two opposite side surfaces of the lamination body or curing the adhesive:
adjusting parallelism and planeness of the lamination body to control an error on each of the parallelism and the planeness within ±5 μm.

6. The process according to claim 2, wherein the lamination body is sealed by using a liquid sealant or a solid sealant, the liquid sealant being an epoxy resin or an acrylic resin, and the solid sealant being a rubber plate or a silicone adhesive,
wherein the liquid sealant has viscosity greater than 20000 cps, and is hardened through normal-temperature natural hardening, heating hardening, or ultraviolet irradiation hardening; and
wherein the hardened liquid sealant has shore hardness ranging from 20 A to 70 A.

7. The process according to claim 2, wherein the adhesive is defoamed before being injected;
the adhesive has viscosity smaller than 500 cps;
the adhesive is an epoxy resin or an acrylic resin; and
the cured adhesive has a volume shrinkage rate smaller than 1.1%, shore hardness ranging from 60 D to 80 D, and a refractive index same as a refractive index of the transparent substrate.

8. The process according to claim 2, wherein the adhesive is injected through one of a first gravity injection, a second gravity injection, a first pressure injection, a second pressure injection, and a vacuum injection,
wherein the first gravity injection comprises:
placing the adhesive introducing surface of the lamination body in an adhesive pool of a gravity adhesive feeding device;
connecting sealingly the gravity adhesive feeding device and the adhesive introducing surface through a sealing material or a sealing tool;
placing the lamination body and the adhesive feeding device into a vacuum chamber of a vacuum device;
filling the gap with the adhesive through gravity of the adhesive and a capillary of the adhesive;
closing the vacuum device in response to observing the adhesive uniformly seeps at all positions of the adhesive discharging surface; and
completing the injection of the adhesive;
wherein the second gravity injection comprises:
placing the adhesive introducing surface of the lamination body in an adhesive pool of a gravity adhesive feeding device;
connecting sealingly the gravity adhesive feeding device and the adhesive introducing surface through a sealing material or a sealing tool;
connecting a vacuum device at the adhesive discharging surface to wrap the entire adhesive discharging surface of the lamination body;
isolating the adhesive discharging surface from an external environment through the sealing material or the sealing tool;
setting an absolute vacuum degree of the vacuum device to be smaller than 10 kpa;
closing the vacuum device in response to observing the adhesive uniformly seeps at all positions of the adhesive discharging surface; and
completing the injection of the adhesive;
wherein the first pressure injection comprises:
placing the adhesive introducing surface of the lamination body in an adhesive of a pressure adhesive feeding device;
connecting sealingly the pressure adhesive feeding device and the adhesive introducing surface through a sealing material or a sealing tool;
applying a mechanical pressure to the adhesive to allow the gap to be full of the adhesive;
monitoring an adjustment pressure by a pressure sensor mounted at the pressure adhesive feeding device to control an adhesive feeding speed;
closing a pressure applying device in response to observing the adhesive uniformly seeps at all positions of the adhesive discharging surface; and
completing the injection of the adhesive;
wherein the second pressure injection comprises:
placing the adhesive introducing surface of the lamination body in an adhesive of a pressure adhesive feeding device;
connecting sealingly the pressure adhesive feeding device and the adhesive introducing surface through a sealing material or a sealing tool;
applying an atmospheric pressure to allow the gap to be full of the adhesive;
monitoring an adjustment air pressure by a gas flow valve mounted at the pressure adhesive feeding device to control an adhesive feeding speed;
closing a pressure applying device in response to observing the adhesive uniformly seeps at all positions of the adhesive discharging surface; and
completing the injection of the adhesive; and
wherein the vacuum injection comprises:
immersing the adhesive introducing surface of the lamination body in an adhesive pool containing the adhesive to liquid-seal the entire adhesive introducing surface by the adhesive;
connecting a vacuum device at the adhesive discharging surface to wrap the entire adhesive discharging surface of the lamination body by the vacuum device;
isolating the adhesive discharging surface from an external environment through a sealing material or a sealing tool;
setting an absolute vacuum degree of the vacuum device to be smaller than 10 kpa;
closing the vacuum device in response to observing the adhesive uniformly seeps at all positions of the adhesive discharging surface; and
completing the injection of the adhesive.

9. The process according to claim 1, wherein said bonding the plurality of quantum dot units comprises:
placing, subsequent to a first one of the plurality of quantum dot units being coated with the adhesive, a second one of the plurality of quantum dot units on the adhesive for bonding, repeating this process to form a laminated structure; and
adjusting parallelism and flatness of the laminated structure prior to curing the laminated structure.

10. The process according to claim 9, wherein the adhesive preferably has viscosity smaller than 1000 cps;
the adhesive is an epoxy resin or an acrylic resin; and
the cured adhesive has a volume shrinkage rate smaller than 1.1% and shore hardness ranging from 60D to 80D.

11. The process according to claim 1, wherein processing the plurality of quantum dot units comprises:
coating a first photoresist layer at a side of the transparent substrate;
exposing and developing to retain a part of the first photoresist layer to form a first residue portion;
plating the first transparent conductive layer at an exposure and development side of the transparent substrate;
peeling the first residue portion to form a first protrusion on the first transparent conductive layer, wherein the first protrusion is located at a side of a peeling region, and is configured to be connected to a first electrode;
coating the quantum dot layer at a side where the first transparent conductive layer is located;
coating a second photoresist layer;
exposing and developing to retain a part of the second photoresist layer to form a second residue portion, wherein the second residue portion and the first residue portion are arranged close to an edge of the transparent substrate;
plating the second transparent conductive layer at the exposure and development side of the transparent substrate; and
peeling the second residual portion to form a second protrusion on the second transparent conductive layer, wherein the second protrusion is located at a side of the second residual portion, and is configured to be connected to a second electrode, and wherein the first protrusion is offset from the second protrusion.

12. A processing method for a three-dimensional display element, the processing method comprising:
the process for the quantum dot complex according to claim 1; and
providing a first electrode and a second electrode outside the quantum dot complex, wherein the first electrode is electrically connected to a first transparent conductive layer of each quantum dot unit, and wherein the second electrode is electrically connected to a second transparent conductive layer of each quantum dot unit; and
attaching a circuit board to a side of the quantum dot complex, and connecting the circuit board to the first electrode and the second electrode.

13. The processing method according to claim 12, wherein said bonding the plurality of quantum dot units comprises:
providing a spacer on at least one side of each of the plurality of quantum dot units, wherein the spacer is a transparent high polymer material member, a resin member, an optical glass member, or an optical crystal member;
laminating the plurality of quantum dot units to form a lamination body, wherein adjacent ones of the plurality of quantum dot units are spaced apart from each other by the spacer to form a gap for accommodating an adhesive;
sealing two opposite side surfaces of the lamination body, and using another two opposite side surfaces of the lamination body as an adhesive introducing surface and an adhesive discharging surface; and
injecting the adhesive to introduce the adhesive from the adhesive introducing surface and fill the gap, to form a layer of cured adhesive containing the spacer between the adjacent quantum dot units.

14. The processing method according to claim 13, wherein the spacer has a height ranging from 1 μm to 500 μm;
a distance between adjacent spacers ranges from 0.1 mm to 5 mm; and
an error on the heights of a plurality of spacers is smaller than or equal to 2 μm.

15. The processing method according to claim 13, wherein a distance between adjacent spacers ranges from 5 μm to 20 mm;
the spacer is selectable from one of silicon dioxide microsphere, polystyrene microsphere, and polymethyl methacrylate microsphere; and
the spacer has a spherical diameter ranging from 1 μm to 200 μm, an error on consistency of the diameter being smaller than 10%.

16. A quantum dot complex, comprising:
a plurality of quantum dot units sequentially laminated and bonded to each other in a thickness direction, each of the plurality of quantum dot units comprising a transparent substrate, a first transparent conductive layer, a second transparent conductive layer, and a quantum dot layer,
wherein the first transparent conductive layer and the quantum dot layer are located at a side of the transparent substrate and sequentially arranged away from the transparent substrate;
wherein the second transparent conductive layer is located at another side of the transparent substrate or located outside the quantum dot layer;
wherein one of the first transparent conductive layer and the second transparent conductive layer is a P-type semiconductor, and another one of the first transparent conductive layer and the second transparent conductive layer is an N-type semiconductor; and
wherein the quantum dot layer, the first transparent conductive layer, and the second transparent conductive layer of a quantum dot unit where the first transparent conductive layer is located or of a quantum dot unit adjacent to the quantum dot unit where the first transparent conductive layer is located are formed as a PN junction.

17. The quantum dot complex according to claim 16, wherein the quantum dot complex has a surface formed as a laser incident surface; and
in a lamination direction of the quantum dot units, the farther a quantum dot unit is from the laser incident surface, the thicker the quantum dot unit is.

18. The quantum dot complex according to claim 16, wherein the quantum dot layer has a thickness ranging from 0.05 μm to 10 μm;
the transparent substrate has a thickness ranging from 0.1 mm to 0.5 mm;
an error on each of parallelism and planeness of each of an upper smooth surface and a lower smooth surface of the transparent substrate is smaller than or equal to ±2 μm; and
a length a and a width b of the transparent substrate satisfy 1 mm≤a≤500 mm, and 1 mm≤b≤500 mm.

19. The quantum dot complex according to claim 16, wherein a quantum dot layer of each quantum dot unit is configured to emit light in one color when being irradiated; or
every three adjacent quantum dot units are defined as a color adjustment group, quantum dot layers of three quantum dot units in each color adjustment group being configured to respectively emit red light, green light, and blue light when being irradiated.

20. A three-dimensional display element, comprising:
the quantum dot complex according to claim 16; and
a circuit board electrically connected to a first transparent conductive layer and a second transparent conductive layer of each quantum dot unit by a first electrode and a second electrode, respectively.
